(19) United States
(12) Patent Application Publication
(10) Pub. No.: US 2026/0362735 A1
(43) Pub. Date: Nov. 12, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Yu Hsing LIN, Tainan (TW); Chun Wei CHEN, Hsinchu (TW); Yen CHUANG, Hsinchu (TW); Chien-Chia CHENG, Hsinchu (TW); Ming-Hua YU, Hsinchu (TW)

(21) Appl. No.: 19/202,450

(22) Filed: May 8, 2025

(51) Int. Cl. H10D 30/00; H10D 30/01; H10D 62/00; H10D 62/13

(52) U.S. Cl. CPC H10D 30/501; H10D 30/019; H10D 62/021; H10D 62/151

(57) ABSTRACT

Embodiments of the present disclosure provide a semiconductor device structure that includes an isolation structure extending over a substrate, an interlayer dielectric (ILD) layer disposed over the isolation structure, a contact etch stop layer disposed between the ILD layer and the isolation structure, a channel region comprising a first plurality of semiconductor layers, and a source/drain feature having a first epitaxial layer adjacent to the first plurality of semiconductor layers, a second epitaxial layer over the first epitaxial layer, and a third epitaxial layer interfacing the first and second epitaxial layers, wherein the first epitaxial layer and the second epitaxial layer are doped with a dopant, and wherein a concentration of the dopant in the first epitaxial layer is different from a concentration of the dopant in the second epitaxial layer.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, and 5 are perspective views of various stages of manufacturing a semiconductor device structure, in accordance with some embodiments.

FIGS. 6, 7, 8, 9, 10, 11, 12, 13, 14, 15, 16, 17, 18, 19, 20, 21, 22, 23, 24, 25, 26, 27, and 28 are cross-sectional side views of various stages of manufacturing the semiconductor device structure taken along line A-A of FIG. 5, in accordance with some embodiments.

FIGS. 29A, 29B, 29C, 29D, 29E, and 29F are cross-sectional side views showing various formations of B clusters in the semiconductor device structure of FIG. 28, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

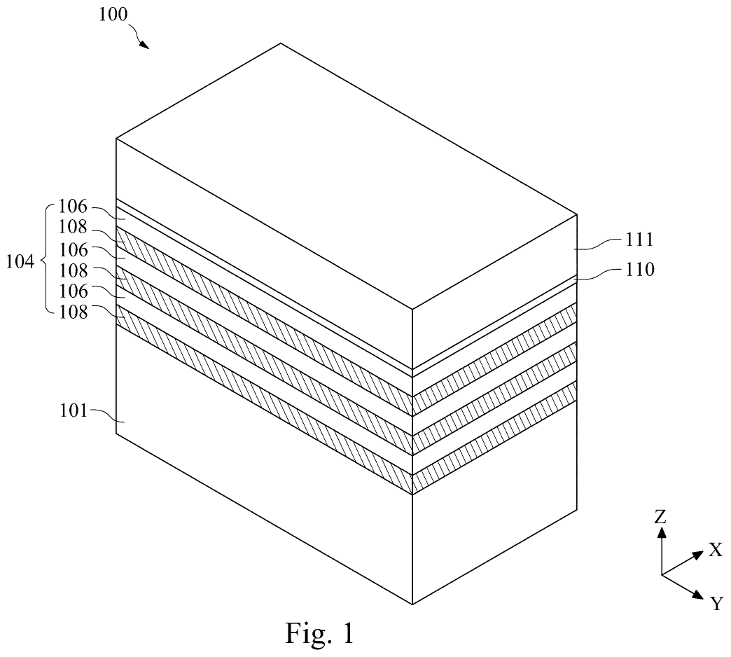

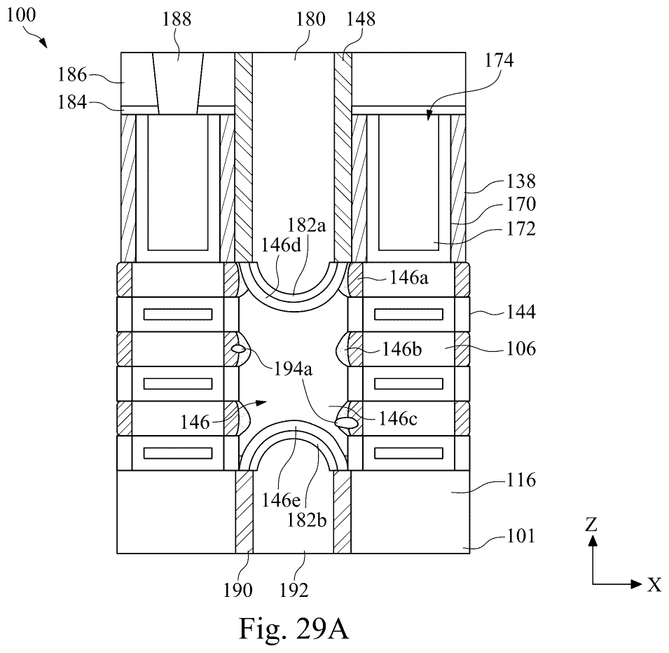

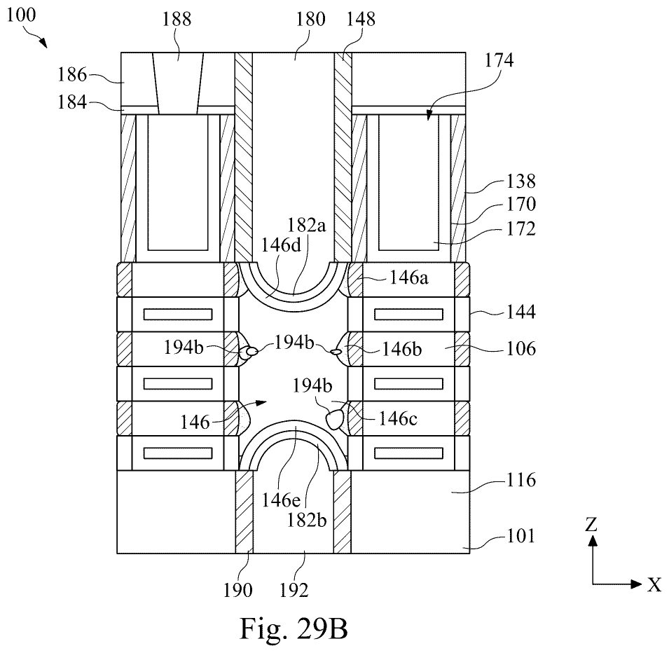

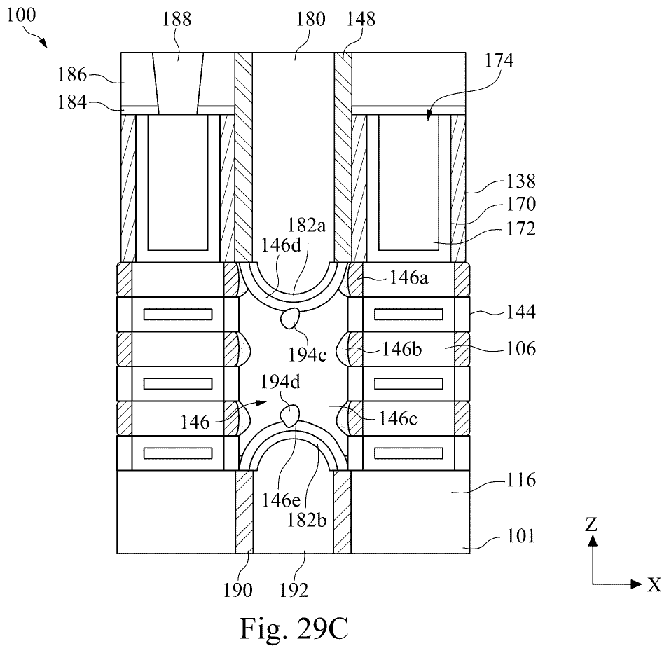

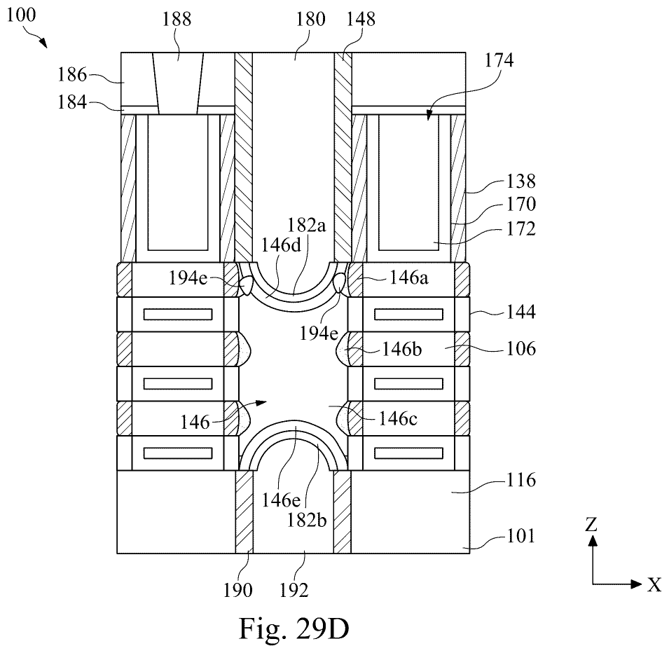

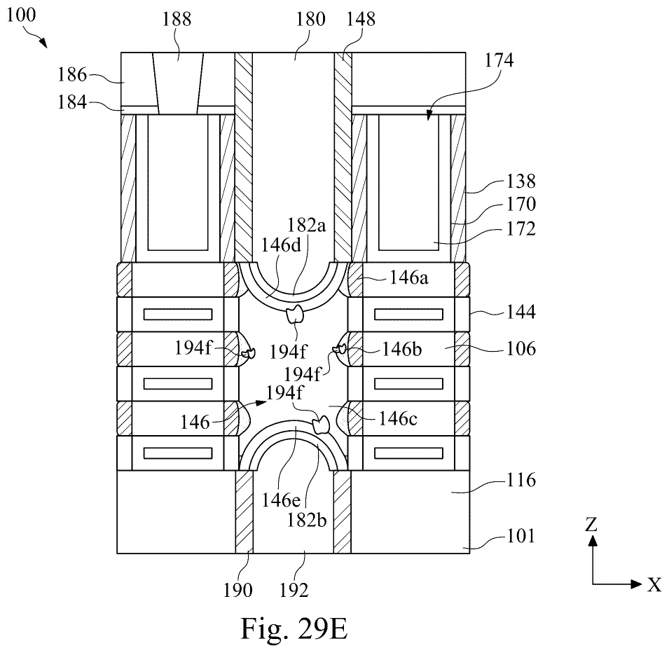

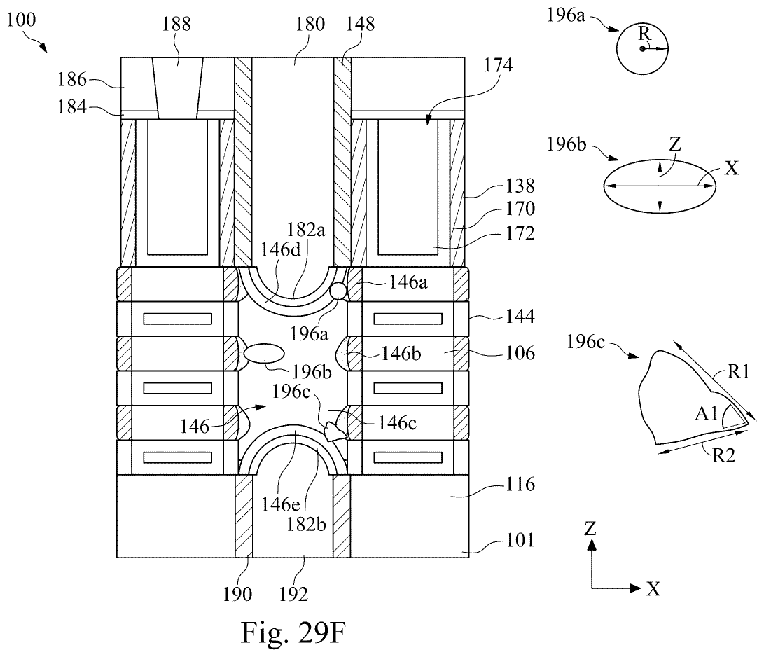

FIGS. 1-28 show exemplary processes for manufacturing a semiconductor device structure 100 according to embodiments of the present disclosure. FIGS. 29A-29F show exemplary formations of boron (B) clusters in the semiconductor device structure 100 according to embodiments of the present disclosure. It is understood that additional operations can be provided before, during, and after processes shown by FIGS. 1-28 and 29A-29F, and some of the operations described below can be replaced or eliminated, for additional embodiments of the method. The order of the operations/processes is not limiting and may be interchangeable.

FIGS. 1-5 are perspective views of various stages of manufacturing a semiconductor device structure 100, in accordance with some embodiments. As shown in FIG. 1, a semiconductor device structure 100 includes a stack of semiconductor layers 104 formed over a frontside of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 3 nm and about 30 nm, such as from about 3 nm to about 10 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. As shown in FIG. 1, an oxide layer 110 is formed on the topmost first semiconductor layer 106, and a nitride layer 111 is formed on the oxide layer 110. The oxide layer 110 may be silicon oxide and may have different etch selectivity compared to the nitride layer 111. The nitride layer 111 may include any suitable nitride material, such as silicon nitride. In some embodiments, the oxide layer 110 and the nitride layer 111 may be a mask structure.

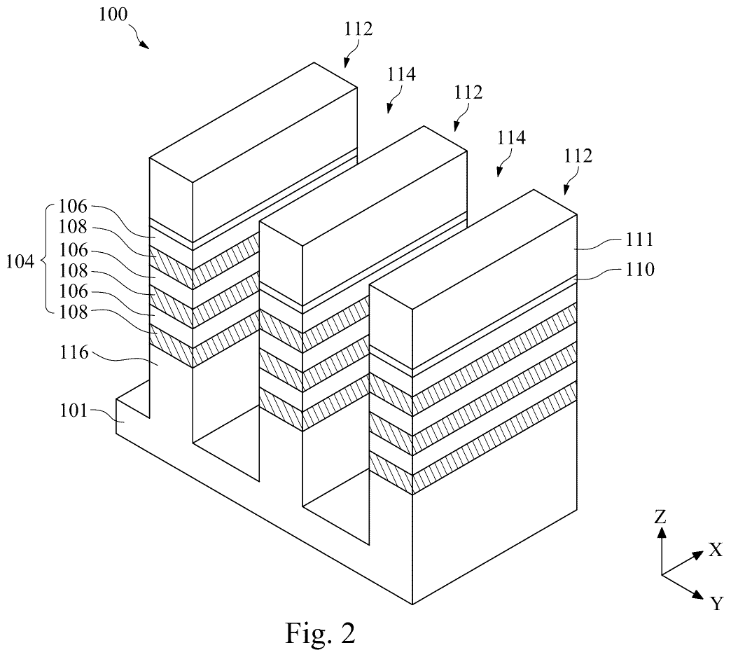

In FIG. 2, fin structures 112 are formed from the stack of semiconductor layers 104. The fin structures 112 defined by the semiconductor layers 104 may be referred to as active region(s). Each fin structure 112 has an upper portion including the semiconductor layers 106, 108 and a substrate portion 116 formed from the substrate 101. The fin structures 112 may be formed by patterning a hard mask layer, such as the oxide layer 110 and the nitride layer 111, using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combinations thereof.

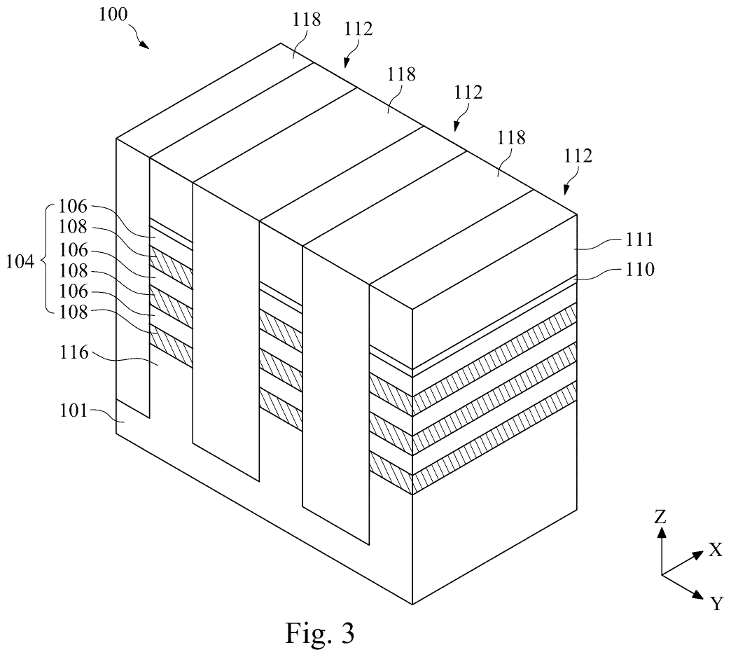

In FIG. 3, an insulating material 118 is formed on the substrate 101. In some embodiments, before the insulating material 118 is formed, a silicon liner (not shown) may be formed in the trenches 114, followed by forming an oxide liner (not shown) over the silicon liner. As shown in FIG. 3, the insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is e xposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

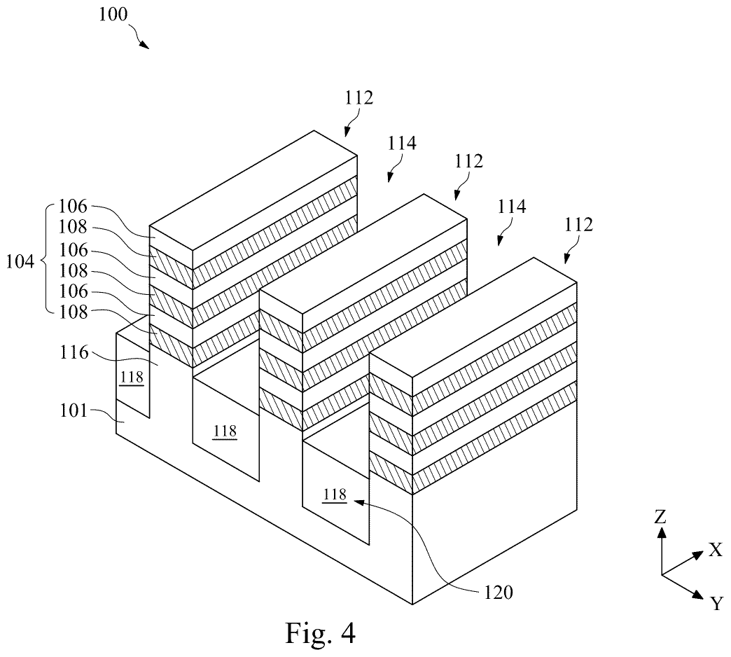

In FIG. 4, the insulating material 118 is recessed to form isolation regions 120 extending over the substrate 101. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the isolation regions 120 may be level with or below a surface of the second semiconductor layers 108 in contact with the substrate portion 116 formed from the substrate 101. In some embodiments, the isolation regions 120 are the shallow trench isolation (STI) regions. In some embodiments, the isolation regions 120 have a dielectric constant (k value) that is about 3 to about 5. In some embodiments, the process to recess the insulating material 118 also removes the oxide layer 110 and the nitride layer 111, as shown in FIG. 4.

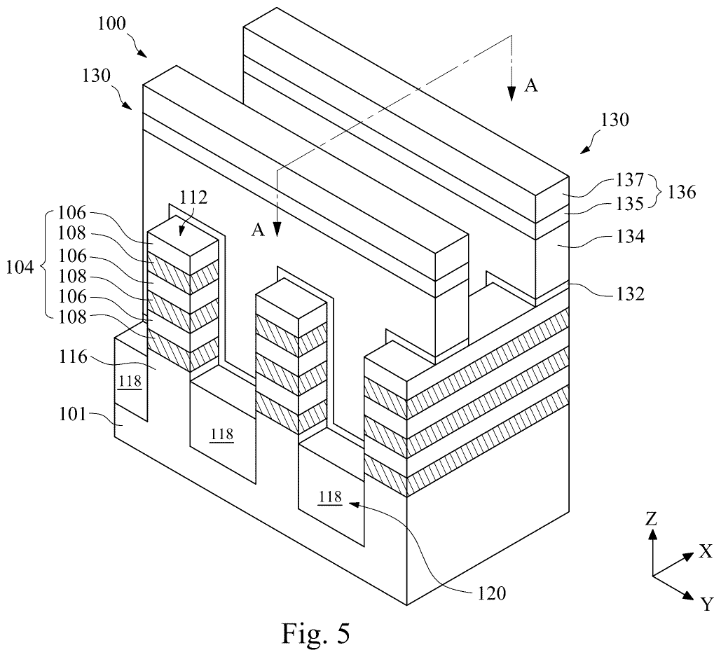

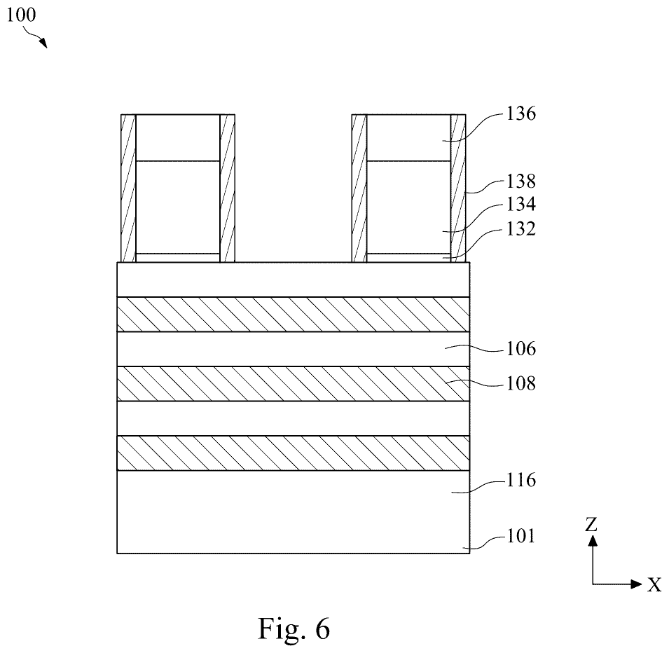

In FIGS. 5-6, one or more sacrificial gate structures 130 are formed over the semiconductor device structure 100. FIG. 6 is a cross-sectional side view of the semiconductor device structure 100 taken along line A-A of FIG. 5. The sacrificial gate structures 130 are formed over first portions of the fin structures 112 and first portions of the isolation regions 120, while second portions of the fin structures 112 and second portions of the isolation regions 120 are exposed. Each sacrificial gate structure 130 may include a sacrificial gate dielectric layer 132, a sacrificial gate electrode layer 134, and a mask layer 136. In some embodiments, the mask layer 136 is a multi-layer structure. For example, the mask layer 136 includes an oxide layer 135 and a nitride layer 137 formed on the oxide layer 135. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. The sacrificial gate dielectric layer 132 may include one or more layers of dielectric material, such as a silicon oxide-based material. The sacrificial gate electrode layer 134 may include silicon, such as polycrystalline silicon or amorphous silicon. The first portions of the fin structures 112 that are covered by the sacrificial gate electrode layer 134 of the sacrificial gate structure 130 serve as channel regions for the semiconductor device structure 100. As shown in FIG. 6, gate spacers 138 are then formed on sidewalls of the sacrificial gate structures 130. The gate spacers may be formed by conformally depositing one or more layers of material and anisotropically etching the one or more layers, for example. The gate spacers 138 may be made of a dielectric material such as silicon oxide, silicon nitride, silicon carbide, silicon oxynitride, SiCN, silicon oxycarbide, SiOCN, and/or combinations thereof.

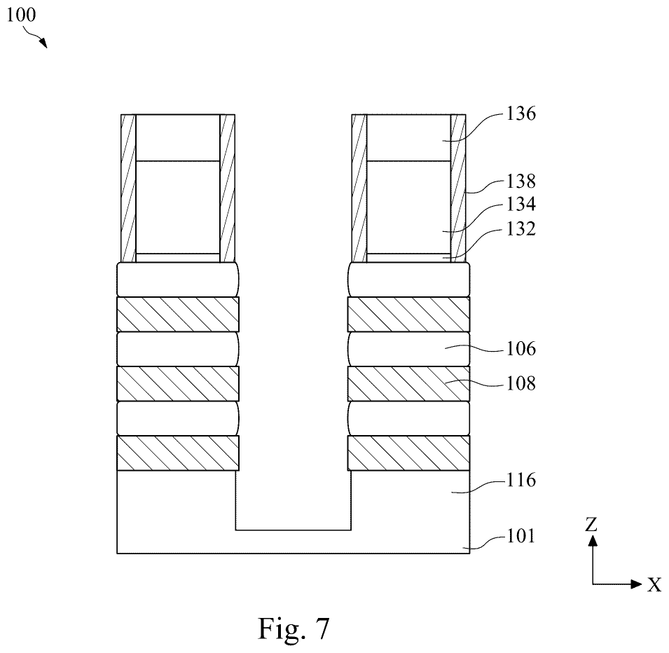

In FIG. 7, the portions of the fin structures 112 not covered by the sacrificial gate structure 130 and the gate spacers 138 are recessed to a level above, at, or below the top surfaces of the isolation regions 120. The recess of the portions of the fin structures 112 can be done by an etch process, either isotropic or anisotropic etch process. The etch process may be a dry etch, such as a RIE, NBE, or the like, or a wet etch, such as using tetramethylammonium hydroxide (TMAH), ammonium hydroxide (NH₄OH), or any suitable etchant. In some embodiments, regions of the semiconductor device structure 100 in which n-type devices or p-type devices are formed are respectively referred to herein as “NMOS regions” or “PMOS regions.” The semiconductor device structure 100 includes PMOS regions and NMOS regions. However, in the following sections and accompanying figures, various stages of manufacturing the PMOS regions are described and illustrated.

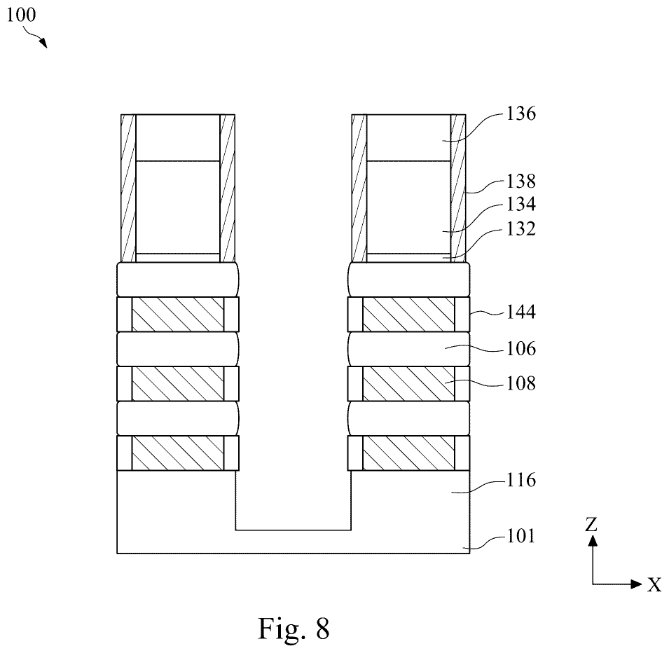

In FIG. 8, edge portions of the second semiconductor layers 108 are removed horizontally along the X direction. In other words, the second semiconductor layers 108 are recessed along the X direction. The removal of the edge portions of the second semiconductor layers 108 forms cavities. In some embodiments, the edge portions of the second semiconductor layers 108 are removed by a selective wet etch process. Next, a dielectric layer (not shown) is deposited on the semiconductor device structure 100 and in the cavities. The dielectric layer may be made of a dielectric material, such as SiO, SiON, SiCN, SiOC, SiOCN, or SiN. The dielectric layer may be formed by a conformal deposition process, such as ALD. As shown in FIG. 8, portions of the dielectric layer are removed to form dielectric spacers 144 in the cavities. In some embodiments, the portions of the dielectric layer are removed by an anisotropic etching process. The dielectric spacers 144 are protected by the first semiconductor layers 106 during the anisotropic etching process. The second semiconductor layers 108 are capped between the dielectric spacers 144 along the X direction.

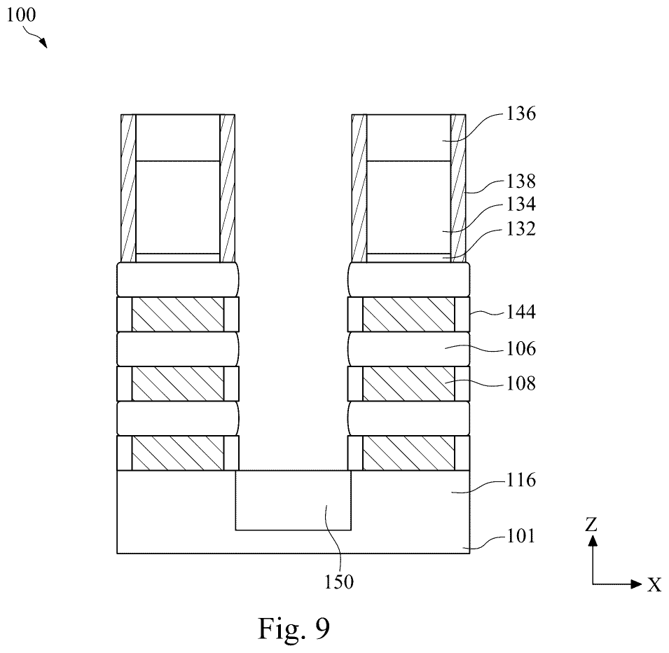

In FIG. 9, a semiconductor layer 150 is formed on the exposed substrate portions 116. The semiconductor layer 150 may be formed adjacent to the substrate portion 116 located under the bottommost second semiconductor layer 108. In some embodiments, the semiconductor layer 150 includes undoped silicon or undoped SiGe. The semiconductor layer 150 may be first formed on semiconductor surfaces, such as on the exposed substrate portions 116 and on the semiconductor layers 106, by epitaxy. In some embodiments, the semiconductor layer 150 is crystalline silicon or crystalline SiGe. A subsequent etch process is performed to remove the portions of the semiconductor layer 150 formed on the first semiconductor layers 106. In some embodiments, the semiconductor layer 150 has a thickness ranging from about 5 nm to about 50 nm along the Z direction.

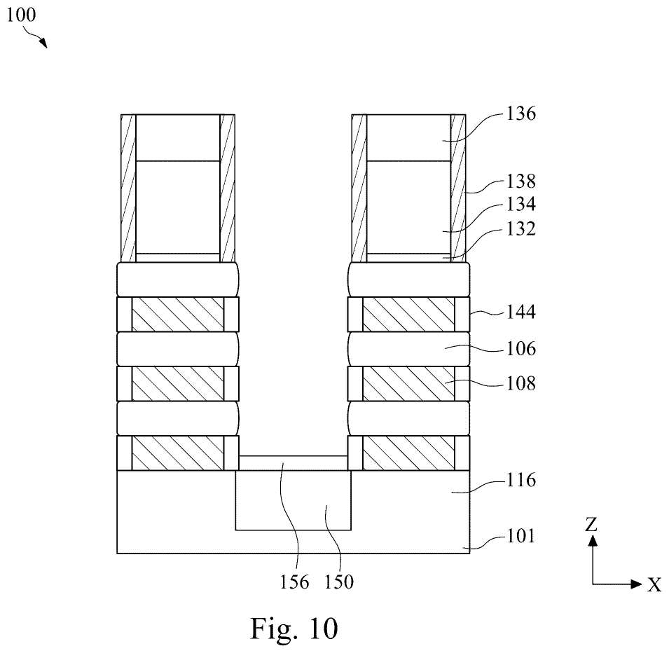

In FIG. 10, a dielectric layer 156 is formed on the semiconductor layer 150. The dielectric layer 156 may be formed by first forming a dielectric layer on the exposed surfaces of the semiconductor device structure 100, followed by one or more etch processes to remove portions of the dielectric layer other than the dielectric layer 156. A sacrificial layer (not shown), such as a bottom anti-reflective coating (BARC) layer, may be used to assist with the removal of the portions of the dielectric layer formed on the sidewalls of the gate spacers 138, the first semiconductor layers 106, and the dielectric spacers 144. The dielectric layer 156 may include any suitable dielectric material. In some embodiments, the dielectric layer 156 includes SiN. The dielectric layer 156 may be formed by any suitable process. In some embodiments, the dielectric layer 156 is formed by CVD or PECVD.

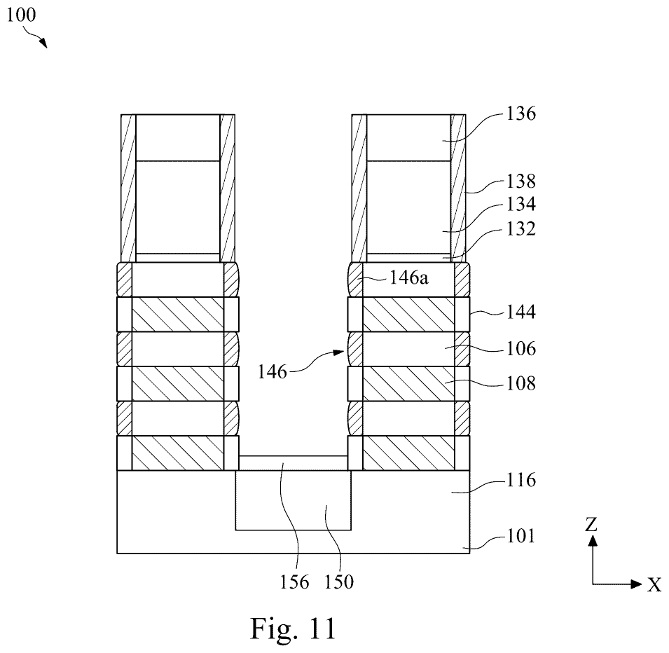

In FIG. 11, an etch process is performed to enlarge the opening between adjacent stacks of first semiconductor layers 106 along the X direction. The etch process may be an isotropic etch process. In some embodiments, the etch process is a wet etch process. In some embodiments, the etch process utilizes an etchant that etches semiconductor materials at a faster rate than dielectric materials. For example, the etchant may remove portions of the first semiconductor layers 106 while the dielectric layer 156, the dielectric spacers 144, and the gate spacers 138 are substantially unaffected by the etchant. As shown in FIG. 11, a semiconductor material 146a is formed on the first semiconductor layers 106 (e.g., being formed on portions of the first semiconductor layers 106 exposed via the etch process that enlarged the opening along the X direction). In some embodiments, the semiconductor material 146a defines a portion of a source/drain (S/D) feature 146. The semiconductor material 146a may include Si, SiGe, Ge, or other suitable semiconductor material (e.g., having a Ge concentration from 0 atomic percent to 10 atomic percent). In some embodiments, the semiconductor material 146a may include a p-type dopant, such as B (e.g., having a B concentration from 1E21 atoms/cm³ to 2E21 atoms/cm³). The semiconductor material 146a may be formed by an epitaxial growth method using CVD, ALD or MBE, and the semiconductor material 146a is not grown from the dielectric materials of the gate spacers 138, the dielectric spacers 144, and the dielectric layer 156. In some embodiments, a temperature associated with the formation of the semiconductor material 146a is between 400 °C and 850 °C. In some embodiments, a pressure associated with the formation of the semiconductor material 146a is between 10 torr and 100 torr. In some embodiments, a gas associated with the formation of the semiconductor material 146a includes SiH₄, DCS, HCl, GeH₄, Si₂H₆, Ge₂H₆, another suitable gas, or combinations thereof.

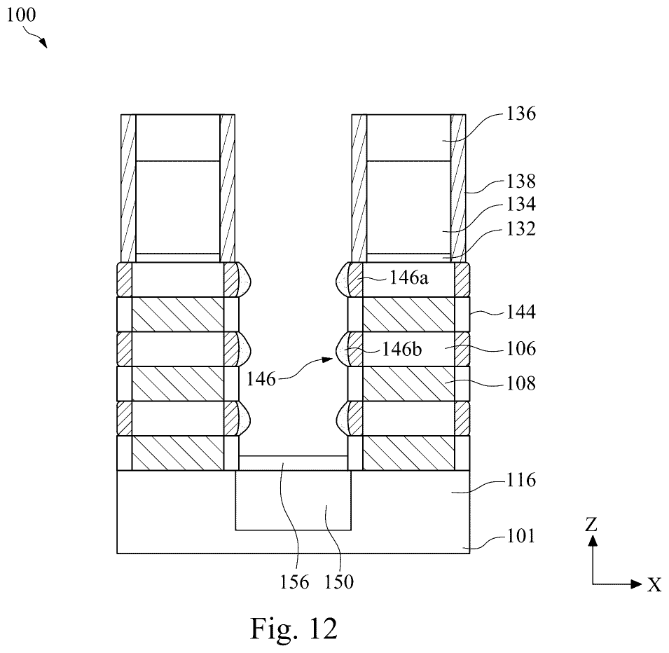

In FIG. 12, a first epitaxial layer 146b is formed on the semiconductor material 146a. The first epitaxial layer 146b defines a portion of the source/drain feature 146. The first epitaxial layer 146b is adjacent to the first semiconductor layers 106. In some embodiments, the semiconductor material 146a is not present, and the first epitaxial layer 146b is formed on (e.g., in contact with) the first semiconductor layers 106. The first epitaxial layer 146b may be formed by an epitaxial growth method using CVD, ALD or MBE. The first epitaxial layer 146b may include Si, SiGe, Ge, or other suitable semiconductor material (e.g., having a Ge concentration from 10 atomic percent to 30 atomic percent). In some embodiments, the first epitaxial layer 146b may include a p-type dopant, such as B (e.g., having a B concentration from 2E20 atoms/cm³ to 1E21 atoms/cm³). In some embodiments, the semiconductor material 146a and the first epitaxial layer 146b include different materials, different compositions, and/or different dopant concentrations. In some embodiments, the Ge concentration of the first epitaxial layer 146b is greater than the Ge concentration of the semiconductor material 146a, and the dopant concentration of the semiconductor material 146a is greater than the dopant concentration of the first epitaxial layer 146b. In some embodiments, a first temperature associated with the formation of the first epitaxial layer 146b is between 400 °C and 850 °C. In some embodiments, a first pressure associated with the formation of the first epitaxial layer 146b is between 10 torr and 100 torr. In some embodiments, a gas associated with the formation of the first epitaxial layer 146b includes SiH₄, DCS, HCl, GeH₄, Si₂H₆, Ge₂H₆, another suitable gas, or combinations thereof.

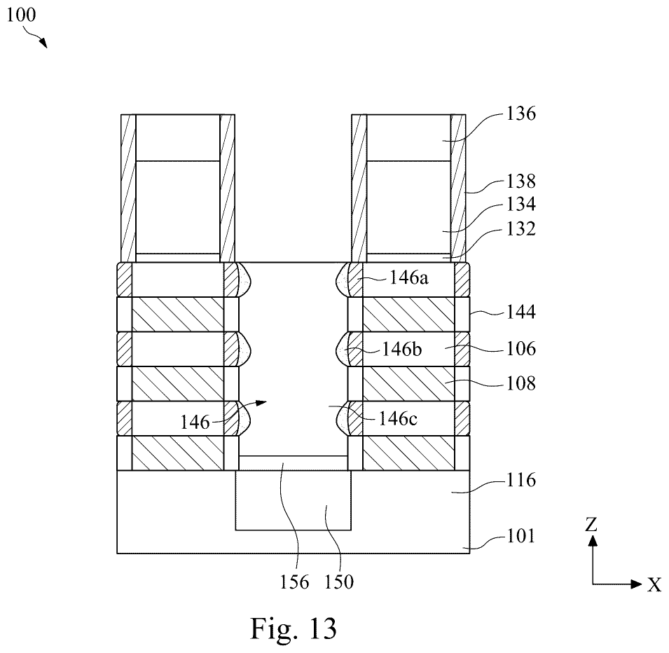

In FIG. 13, a second epitaxial layer 146c is formed over the first epitaxial layer 146b. In some embodiments, the second epitaxial layer 146c is formed on (e.g., in contact with) the first epitaxial layer 146b, as shown in FIG. 13. The second epitaxial layer 146c may be formed by an epitaxial growth method using CVD, ALD or MBE. The second epitaxial layer 146c defines a portion of the source/drain feature 146. The second epitaxial layer 146c may include Si, SiGe, Ge, or other suitable semiconductor material (e.g., having a Ge concentration from 30 atomic percent to 50 atomic percent). In some embodiments, the second epitaxial layer 146c may include a p-type dopant, such as B (e.g., having a B concentration from 5E20 atoms/cm³ to 2E21 atoms/cm³). In some embodiments, the first and second epitaxial layers 146b, 146c include different materials, different compositions, and/or different dopant concentrations. In some embodiments, the Ge concentration of the second epitaxial layer 146c is greater than the Ge concentration of the first epitaxial layer 146b, and the dopant concentration of the second epitaxial layer 146c is greater than the dopant concentration of the first epitaxial layer 146b. In some embodiments, a second temperature associated with the formation of the second epitaxial layer 146c is between 400 °C and 850 °C In some embodiments, the first and second temperatures associated with the formation of the respective first and second epitaxial layers 146b, 146c may be the same or they may be different. In some embodiments, the Ge concentration of the second epitaxial layer 146c may be limited by and/or inversely related to a relatively high processing temperature of the second epitaxial layer 146c compared to later formed epitaxial layers. Even if it was desired to form the second epitaxial layer 146c at a somewhat lower processing temperature to increase the Ge concentration, doing so would result in very long processing times because of the relatively large size of the second epitaxial layer 146c. In some embodiments, a second pressure associated with the formation of the second epitaxial layer 146c is between 10 torr and 100 torr. In some embodiments, a gas associated with the formation of the second epitaxial layer 146c includes SiH₄, DCS, HCl, GeH₄, Si₂H₆, Ge₂H₆, another suitable gas, or combinations thereof.

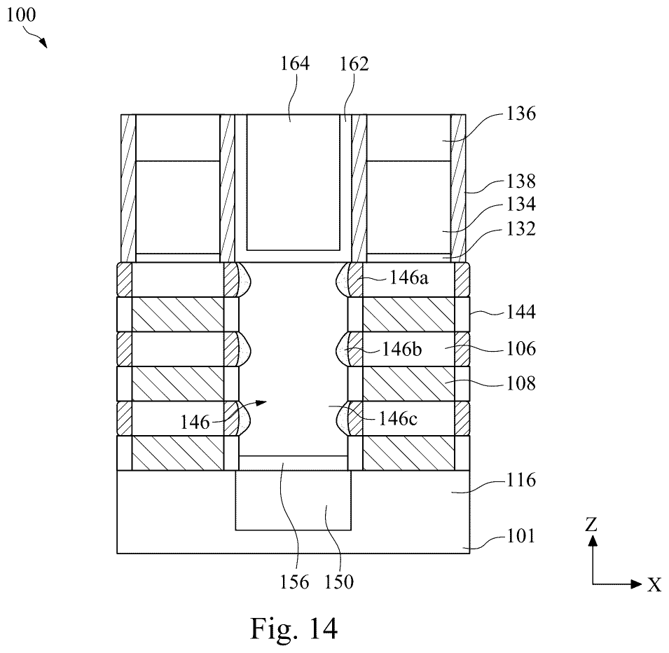

In FIG. 14, a contact etch stop layer (CESL) 162 is conformally formed on the exposed surfaces of the semiconductor device structure 100. The CESL 162 is disposed over and covers the gate spacers 138, the S/D features 146 (e.g., formed on first and/or second epitaxial layers 146b, 146c), and the isolation regions 120. The CESL 162 may include a nitrogen-containing material, such as silicon nitride, and may be formed by CVD, PECVD, ALD, or any suitable deposition technique. Next, an interlayer dielectric (ILD) layer 164 is formed on the CESL 162 over the semiconductor device structure 100. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, the ILD layer 164 has a dielectric constant (k value) that is about 3 to about 5. In some embodiments, after formation of the ILD layer 164, the semiconductor device structure 100 may be subject to a thermal process to anneal the ILD layer 164. After the ILD layer 164 is formed, a planarization operation, such as CMP, is performed on the semiconductor device structure 100 until the sacrificial gate electrode layer 134 is exposed.

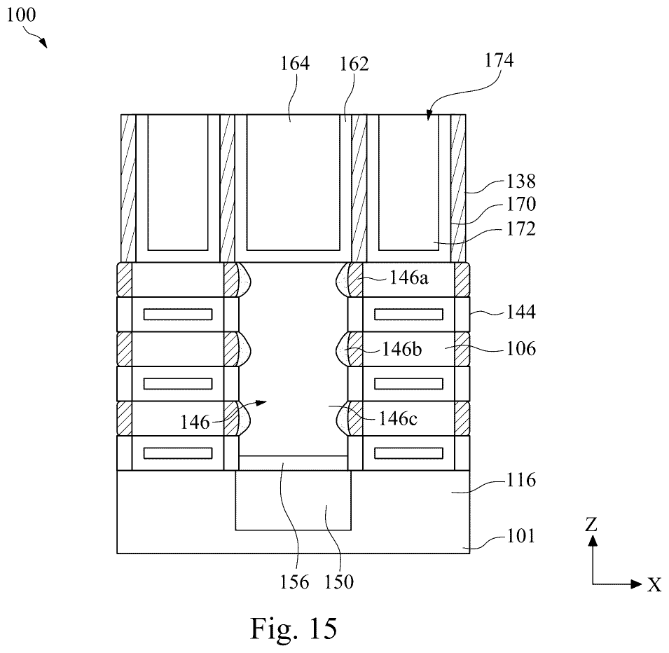

In FIG. 15, the sacrificial gate electrode layer 134, the sacrificial gate dielectric layer 132, and the second semiconductor layers 108 are removed, exposing portions of the first semiconductor layers 106. In some embodiments, portions of the isolation regions 120 are exposed by removal of the sacrificial gate dielectric layer 132. The removal of the sacrificial gate structure 130 and the second semiconductor layers 108 forms an opening between the gate spacers 138 and between the first semiconductor layers 106. The ILD layer 164 protects the S/D features 146 during the removal processes. The sacrificial gate electrode layer 134 may be first removed by any suitable process, such as dry etch, wet etch, or a combination thereof, followed by the removal of the sacrificial gate dielectric layer 132, which may be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the gate spacers 138, the ILD layer 164, and the CESL 162. In some embodiments, the second semiconductor layers 108 are removed by a selective etch process. The selective etch process removes the second semiconductor layers 108 between the first semiconductor layers 106 but does not remove the first semiconductor layers 106, the ILD layer 164, the CESL 162, and the gate spacers 138. In some embodiments, the sacrificial gate dielectric layer 132 and the second semiconductor layers 108 are removed by the same selective etch process.

After the formation of nanostructure channels (i.e., exposed portions of the first semiconductor layers 106), a gate dielectric layer 170 is formed to surround the exposed portions of the first semiconductor layers 106, and a gate electrode layer 172 is formed on the gate dielectric layer 170, as shown in FIG. 15. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106. The interfacial layer interfaces the first semiconductor layers 106 (e.g., active region). In some embodiments, the gate dielectric layer 170 is formed over the exposed portions of the isolation regions 120. For example, the gate dielectric layer 170 and the isolation regions 120 may intermix at an interface between the gate dielectric layer 170 and the isolation regions 120. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO2, HfSiO, HfSiON, HfTaO, HfTiO, HfZrO, zirconium oxide, aluminum oxide, titanium oxide, hafnium dioxide-alumina (HfO2—Al2O3) alloy, other suitable high-K dielectric materials, and/or combinations thereof. The gate dielectric layer 170 may be formed by CVD, ALD or any suitable deposition technique. The gate electrode layer 172 may include one or more layers of conductive material (e.g., one or more metal layers), such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the upper surface of the ILD layer 164. The gate dielectric layer 170 and the gate electrode layer 172 formed over the ILD layer 164 are then removed by using, for example, CMP, until the top surface of the ILD layer 164 is exposed.

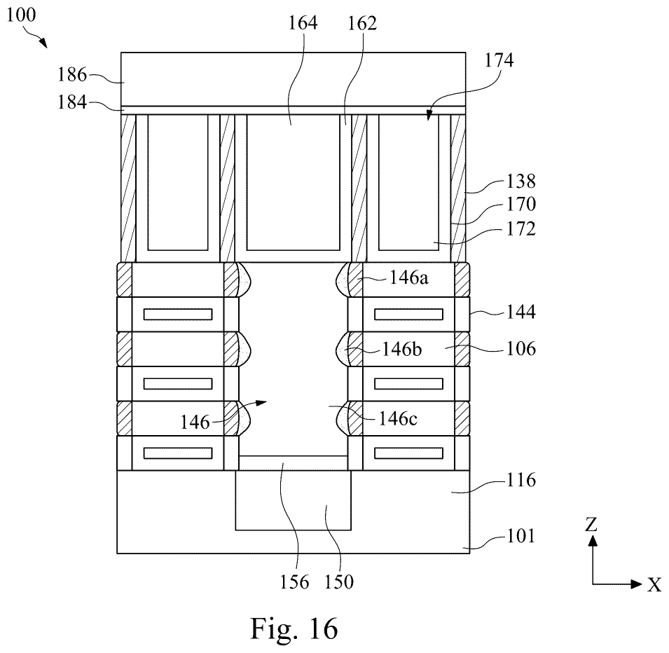

In FIG. 16, an etch stop layer (ESL) 184 is formed over the CESL 162, the ILD layer 164, and the gate structures 174. In some embodiments, the etch stop layer may be disposed over a top surface of the CESL 162 and a top surface of the ILD layer 164. The etch stop layer 184 may be referred to as a middle contact etch stop layer (MCESL). An ILD layer 186 is formed on the etch stop layer 184. In some embodiments, a thickness of the ILD layer 164 is greater than a thickness of the ILD layer 186. In some embodiments, the etch stop layer 184 may include a material different from the CESL 162. For example, the CESL 162 may be made from SiN, and the etch stop layer 184 may be made from a dielectric material having a k value less than that of the CESL 162. In some embodiments, the etch stop layer 184 may include SiO₂, Si₃N₄, SiC, other metal oxides, other suitable materials, and combinations thereof. The etch stop layer 184 may be deposited by a CVD process, PECVD process, or other suitable deposition technique. The ILD layer 186 may include the same material as the ILD layer 164. The ILD layer 186 may be deposited by a PECVD process or other suitable deposition technique.

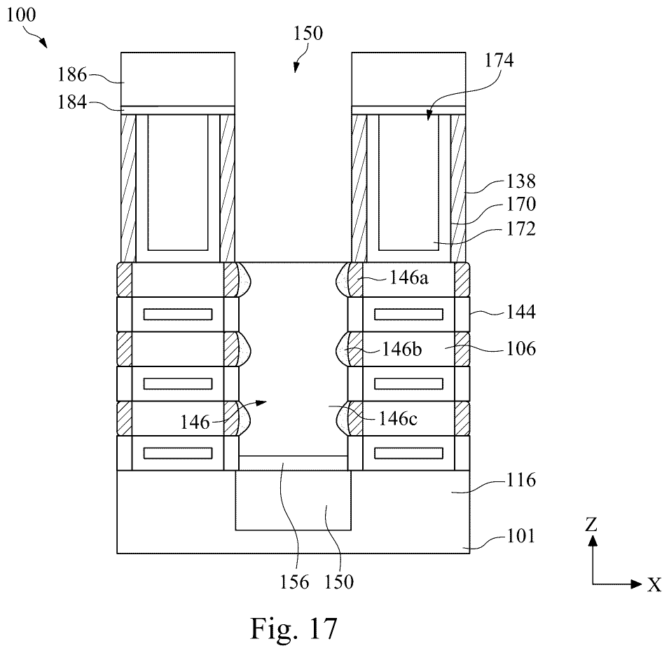

In FIG. 17, one or more etching processes are performed to remove portions of the ILD layer 186, the etch stop layer 184, the ILD layer 164, and the CESL 162 to form an opening 150 between the gate spacers 138 of adjacent gate structures 174. In some embodiments, the opening may be formed by patterning a hard mask layer (not shown) using multi-patterning operations including photo-lithography and etching processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms the opening 150 in unprotected regions through the hard mask layer. The etching process can include anisotropic etching, such as dry etching, wet etching, reactive ion etching (RIE), and/or other suitable processes.

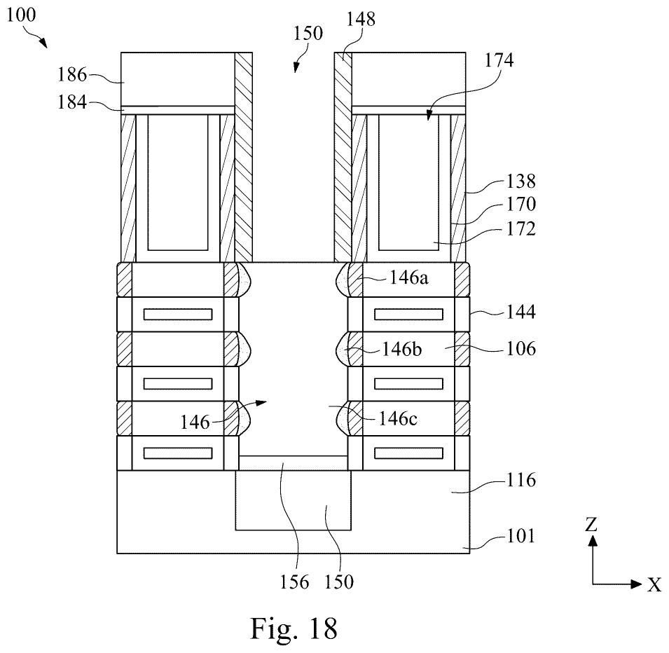

In FIG. 18, a dielectric layer 148 is deposited on the semiconductor device structure 100 and in the opening 150. The dielectric layer 148 may be made of a dielectric material, such as SiO, SiON, SiCN, SiOC, SiOCN, or SiN. The dielectric layer may be formed by a conformal deposition process, such as ALD. As shown in FIG. 18, portions of the dielectric layer 148 may be removed by an anisotropic etch process, such as dry etching, wet etching, reactive ion etching (RIE), and/or other suitable processes.

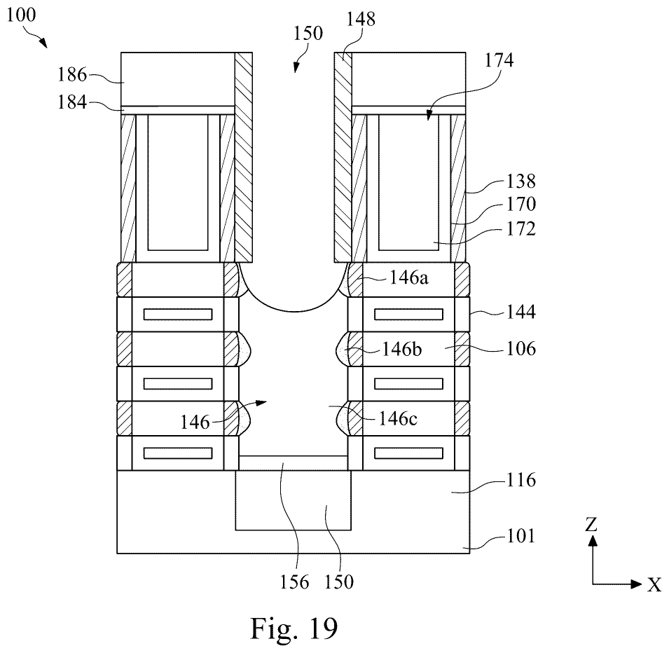

In FIG. 19, an etching process is performed to remove a portion of the second epitaxial layer 146c that is exposed in the opening 150. The etching process can include isotropic etching, such as dry etching, wet etching, and/or other suitable processes. In some embodiments, the etching process is an isotropic etching process, and the portion of the second epitaxial layer 146c located below the dielectric layer 148 is removed, as shown in FIG. 19. As a result, in some embodiments, the first epitaxial layer 146b is exposed in the opening 150.

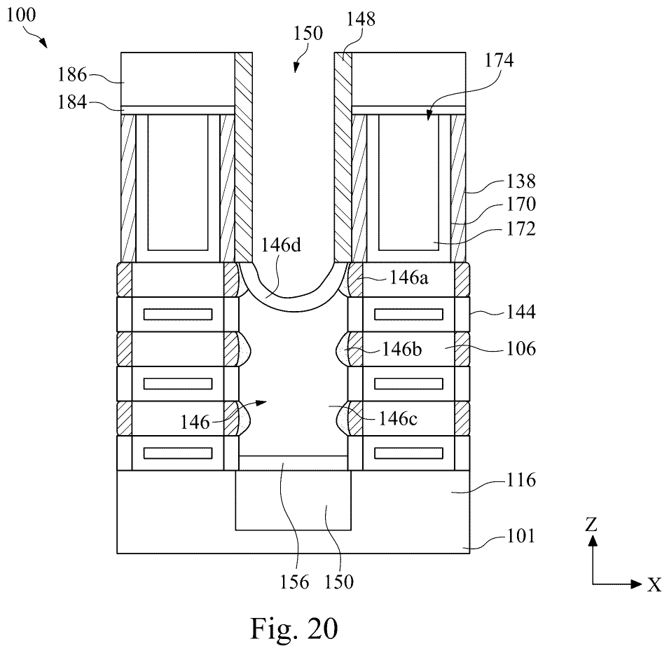

In FIG. 20, a third epitaxial layer 146d is formed over the first and second epitaxial layers 146b, 146c. In some embodiments, the third epitaxial layer 146d is formed on (e.g., interfacing) the first and second epitaxial layers 146b, 146c, as shown in FIG. 20. The third epitaxial layer 146d may be formed by an epitaxial growth method using CVD, ALD or MBE. For example, the third epitaxial layer 146d may be grown from the first and second epitaxial layers 146b, 146c. The second epitaxial layer 146c defines a portion of the source/drain feature 146. The third epitaxial layer 146d may include Si, SiGe, Ge, or other suitable semiconductor material (e.g., having a Ge concentration from 50 atomic percent to 95 atomic percent). In some embodiments, the third epitaxial layer 146d may include a p-type dopant, such as B (e.g., having a B concentration from 1E21 atoms/cm³ to 5E21 atoms/cm³), Ga, or combinations thereof. In some embodiments, a third dopant concentration of the third epitaxial layer 146d may be between 1E21 atoms/cm³ and 5E21 atoms/cm³. In some embodiments, the third dopant concentration of the third epitaxial layer 146d is greater than the second dopant concentration of the second epitaxial layer 146c.

In some embodiments, there is a tradeoff between Ge concentration and B dopant concentration. In some embodiments, a threshold or inflection point may exist for Ge concentrations exceeding a threshold value. For example, at Ge concentrations below the threshold value, Ge concentration and B dopant concentration of the respective epitaxial layer may increase together. However, at Ge concentrations at or above the threshold value, further increases in Ge concentration may result in reducing the B dopant concentration. In some embodiments the threshold value may be between 65 atomic percent and 75 atomic percent Ge, such as about 70 atomic percent Ge. In one example, the second epitaxial layer 146c has a Ge concentration equal to about 40 atomic percent and a B concentration equal to about 5E20 atoms/cm³, and the third epitaxial layer 146d has a Ge concentration equal to about 70 atomic percent and a B concentration equal to about 5E21 atoms/cm³. In this example, the third epitaxial layer 146d has lower contact resistance at least because the Ge and B concentrations are both higher compared to the second epitaxial layer 146c. In another example, the second epitaxial layer 146c has a Ge concentration equal to about 70 atomic percent and a B concentration equal to about 2E21 atoms/cm³, and the third epitaxial layer 146d has a Ge concentration equal to about 95 atomic percent and a B concentration equal to about 1E21 atoms/cm³. In this example, the third epitaxial layer 146d has lower contact resistance even though the B concentration is lower, at least because the comparatively higher Ge concentration makes up the difference. In some embodiments when the third dopant concentration is greater than the second dopant concentration, such as in the first example above, respective Ge concentrations of the second and third epitaxial layers 146c, 146d may each be less than 75 atomic percent, such as less than 70 atomic percent. In other embodiments, the third dopant concentration is less than the second dopant concentration, such as in the second example above. In such embodiments, the Ge concentration of the second epitaxial layer 146c may be less than 70 atomic percent, and the Ge concentration of the third epitaxial layer 146d may be greater than 70 atomic percent.

In some embodiments, based on the differences in semiconductor material compositions and/or dopant concentrations described herein, contact resistance is lower in the third epitaxial layer 146d compared to the second epitaxial layer 146c. In some embodiments, the first, second, and/or third epitaxial layers 146b, 146c, 146d include different materials, different compositions, and/or different dopant concentrations. By forming the third epitaxial layer 146d after forming the dielectric layer 148, the third epitaxial layer 146d is not damaged from the multiple etching processes performed to form the opening 150 and to form the dielectric layer 148. For example, if the third epitaxial layer 146d is formed immediately after the formation of the second epitaxial layer 146c, the etching processes to form the opening 150 and the etching process to form the dielectric layer 148 may damage or remove the third epitaxial layer 146d.

In some embodiments, a third temperature associated with the formation of the third epitaxial layer 146d is between 350 °C and 600 °C. In some embodiments, the third temperature associated with the formation of the third epitaxial layer 146d is lower than respective first and second temperatures associated with the formation of the first and second epitaxial layers 146b, 146c, for example, because lower formation temperature can provide higher concentrations of Ge and/or B in the resulting epitaxial layer. Therefore, it may be desirable to form the third epitaxial layer 146d at a lower temperature than the first and second epitaxial layers 146b, 146c to increase respective concentrations of Ge and/or B to lower the contact resistance in the third epitaxial layer 146d. As described above, if the second epitaxial layer 146c is formed using the lower temperature, the processing time for forming the second epitaxial layer 146c would take too long. In some embodiments, a third pressure associated with the formation of the third epitaxial layer 146d is between 10 torr and 200 torr. In some embodiments, a gas associated with the formation of the third epitaxial layer 146d includes SiH₄, Si₂H₆, Si₃H₈, DCS, HCl, Cl₂, GeH₄, Ge₂H₆, another suitable gas, or combinations thereof.

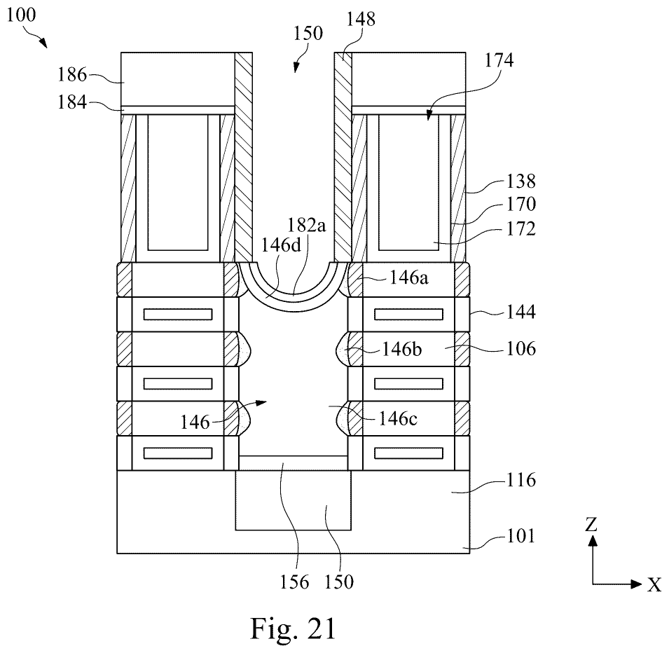

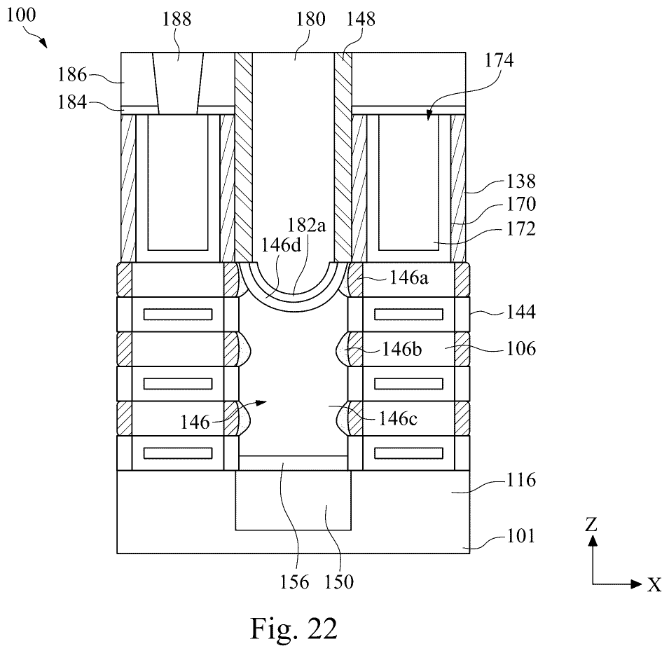

In FIG. 21, a silicide layer 182a is formed over the third epitaxial layer 146d. The silicide layer 182a may be metal silicide layer formed by any suitable process. As shown in FIG. 21, the silicide layer 182a has a curved profile. In some embodiments, an electrical conductivity of the silicide layer 182a is between an electrical conductivity of the respective S/D feature 146 (e.g., the third epitaxial layer 146d) and an electrical conductivity of a respective S/D contact 180 (FIG. 22). In some embodiments, a metal layer (not shown) is first formed on the semiconductor device structure 100. The metal layer may include Ti, Ni, Ru, Co, W, or other suitable metal. The metal layer may be deposited by any suitable process, such as ALD, CVD, or PVD. After the metal layer deposition, an annealing process is performed to react the S/D feature 146 (e.g., the third epitaxial layer 146d) with the metal layer, thereby forming the silicide layer 182a. The silicide layer 182a may include any suitable material, such as NiSi, TiSi, CoSi, RuSi, or WSi.

In FIG. 22, a S/D contact 180 is formed in the opening 150, over the silicide layer 182a, and between the sidewall portions of the dielectric layer 148. The S/D contact 180 is electrically connected to the corresponding S/D feature 146 via the silicide layer 182a. The S/D contact 180 may be electrically conductive and may include a material having one or more of Ru, Mo, Co, Ir, W, Ti, Ta, Cu, TiN or TaN. The S/D contact 180 may be formed by any suitable method, such as electro-chemical plating (ECP) or PVD. In FIG. 22, a conductive contact 188 is deposited in the ILD layer 186 and the etch stop layer 184. The conductive contact 188 may include an electrically conductive material, such as Ru, Mo, Co, Ir, W, Ti, Ta, Cu, TiN, TaN or combinations thereof, or other suitable material. The conductive contact 188 may be formed by any suitable process, such as PVD or ECP. In some embodiments, the conductive contact 188 is electrically connected to the gate electrode layers 172. A planarization process, such as a CMP process, may be performed so the top surfaces of the S/D contact 180, the conductive contact 188, and the ILD layer 186 are substantially co-planar, as shown in FIG. 22.

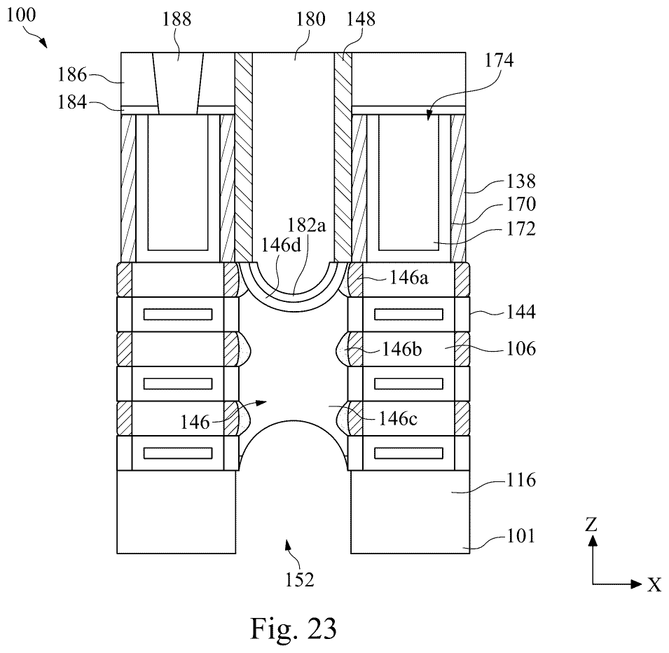

In FIG. 23, after forming an interconnect structure on the frontside, the semiconductor device structure 100 is flipped over for backside process. In some embodiments, an opening 152 is formed on the backside of the substrate 101. In some embodiments, one or more etching processes may be performed to remove portions of the substrate 101, the semiconductor layer 150, the dielectric layer 156, and the second epitaxial layer 146c to form the opening 152 (e.g., between remaining portions of the substrate 101 and the dielectric spacers 144). In some embodiments, the opening 152 may be formed by patterning a hard mask layer (not shown) using multi-patterning operations including photo-lithography and etching processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms the opening 152 in unprotected regions through the hard mask layer. The etching process can include anisotropic etching, such as dry etching, wet etching, reactive ion etching (RIE), and/or other suitable processes.

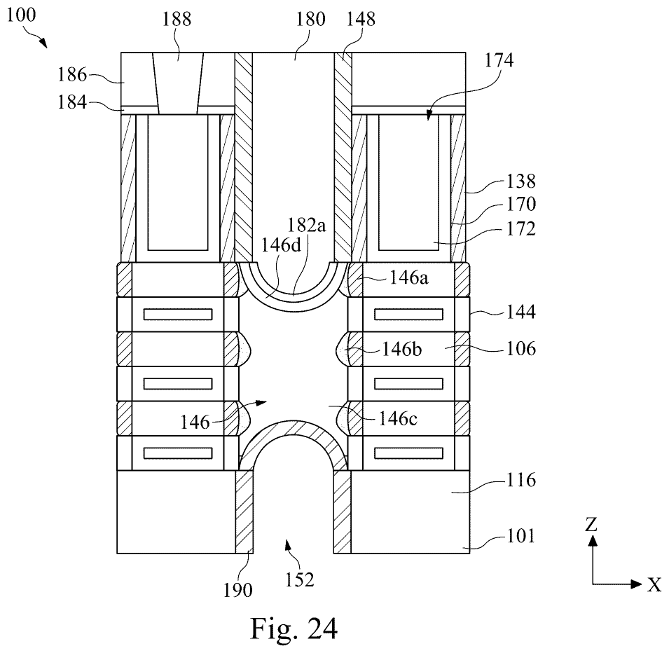

In FIG. 24, a dielectric layer 190 is deposited on the semiconductor device structure 100 and in the opening 152. The dielectric layer 190 may be made of a dielectric material, such as SiO, SiON, SiCN, SiOC, SiOCN, or SiN. The dielectric layer may be formed by a conformal deposition process, such as ALD.

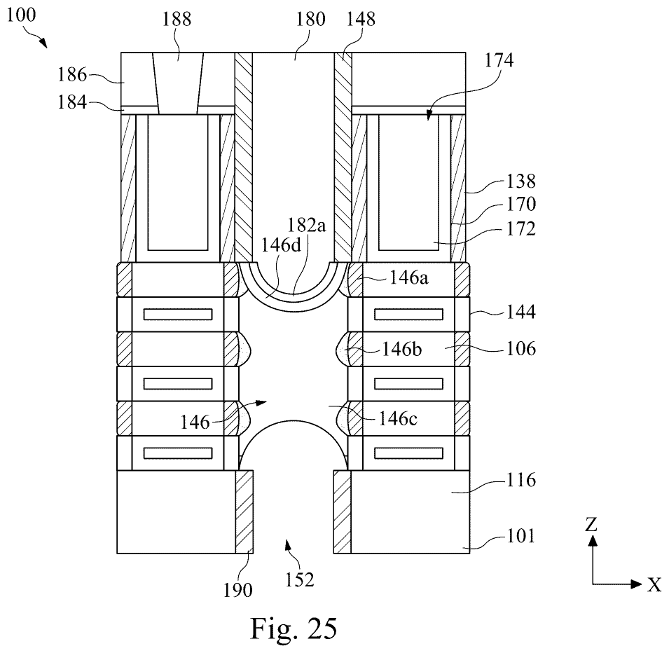

In FIG. 25, portions of the dielectric layer 190 that are in contact with the second epitaxial layer 146c may be removed by an anisotropic etch process, such as dry etching, wet etching, reactive ion etching (RIE), and/or other suitable processes.

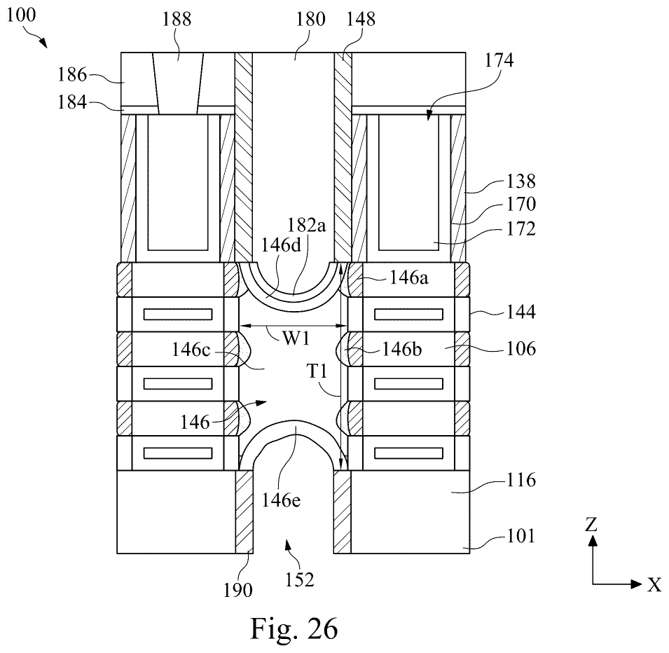

In FIG. 26, a fourth epitaxial layer 146e is formed over the second epitaxial layer 146c. The fourth epitaxial layer 146e defines a portion of the source/drain feature 146. In some embodiments, the fourth epitaxial layer 146e is formed on (e.g., in contact with) the second epitaxial layer 146c, as shown in FIG. 26. In some embodiments, the fourth epitaxial layer 146e is in contact with the dielectric spacers 144, as shown in FIG. 26. The fourth epitaxial layer 146e may be formed by an epitaxial growth method using CVD, ALD or MBE. In some embodiments, the first and second epitaxial layers 146b, 146c are disposed between the third and fourth epitaxial layers 146d, 146e along the Z direction. The fourth epitaxial layer 146e may include Si, SiGe, Ge, or other suitable semiconductor material (e.g., having a Ge concentration from 50 atomic percent to 95 atomic percent). In some embodiments, a composition of the semiconductor material (e.g., Ge or Si content) in the third epitaxial layer 146d is different from a composition of the semiconductor material in the fourth epitaxial layer 146e. In some embodiments, the fourth epitaxial layer 146e may include a p-type dopant, such as B (e.g., having a B concentration from 1E21 atoms/cm³ to 5E21 atoms/cm³), Ga, or combinations thereof. In some embodiments, a concentration of the dopant in the third epitaxial layer 146d is different from a concentration of the dopant in the fourth epitaxial layer 146e.

In some embodiments, a fourth temperature associated with the formation of the fourth epitaxial layer 146e is between 350 °C and 600 °C. In some embodiments, the fourth temperature may be limited to a maximum value that is lower than 600 °C. For example, when the S/D contact 180 and the conductive features (metal lines and metal vias) in the interconnect structure are already formed over the frontside, then the fourth temperature may be limited to a lower maximum value (e.g., 500 °C) that does not damage the material of the S/D contact 180 and the conductive features. In some embodiments, the fourth temperature is lower than the third temperature associated with the formation of the third epitaxial layer 146d, for example, because the third epitaxial layer 146d is formed before the formation of the S/D contact 180. Therefore, there is not a risk of the third temperature associated with the formation of the third epitaxial layer 146d causing damage to the S/D contact 180 as there is during the formation of the fourth epitaxial layer 146e. As a result of the lower fourth temperature, the Ge concentration of the fourth epitaxial layer 146e is greater than the Ge concentration of the third epitaxial layer 146d. In some embodiments, the Ge concentrations of the third and fourth epitaxial layers 146d, 146e are both below 70 atomic percent, and the dopant concentration of the fourth epitaxial layer 146e is greater than the dopant concentration of the third epitaxial layer 146d. In some embodiments, the Ge concentration of the third epitaxial layer 146d is below 70 atomic percent, the Ge concentration of the fourth epitaxial layer 146e is greater than 70 atomic percent, and the dopant concentration of the third epitaxial layer 146d is greater than the dopant concentration of the fourth epitaxial layer 146e. In some embodiments, the Ge concentrations of the third and fourth epitaxial layers 146d, 146e are both greater than 70 atomic percent, and the dopant concentration of the third epitaxial layer 146d is greater than the dopant concentration of the fourth epitaxial layer 146e.

In some embodiments, based on the differences in semiconductor material compositions and/or dopant concentrations described herein, contact resistance is lower in the fourth epitaxial layer 146e compared to the second epitaxial layer 146c. Lower contact resistance may be associated with improved device performance. However, to achieve the improved device performance, contact resistance may only need to be lower in a portion of the source/drain feature 146 that is adjacent to the S/D contact 180 and not throughout the entire source/drain feature 146. In other words, contact resistance of the third and fourth epitaxial layers 146d, 146e may have greater impact on device performance than contact resistance of the second epitaxial layer 146c, which is further away from the S/D contact 180. In some embodiments, the first, second, third, and/or fourth epitaxial layers 146b, 146c, 146d, 146e include different materials, different compositions, and/or different dopant concentrations. As shown in FIG. 26, the source/drain feature 146 (e.g., including the semiconductor material 146a, first, second, third, and/or fourth epitaxial layers 146b, 146c, 146d, 146e) defines a width W1 and a thickness T1. In some embodiments, the thickness T1 of the source/drain feature 146 is different from the width W1 of the source/drain feature 146 in a cross-sectional view.

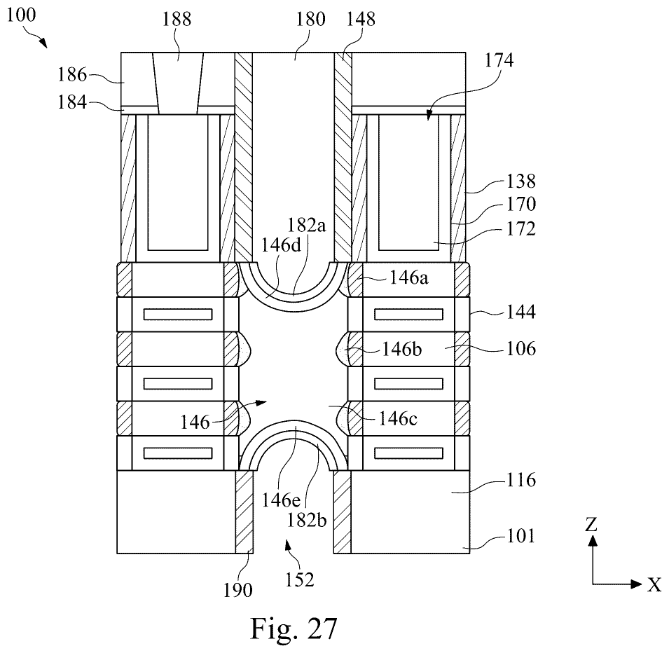

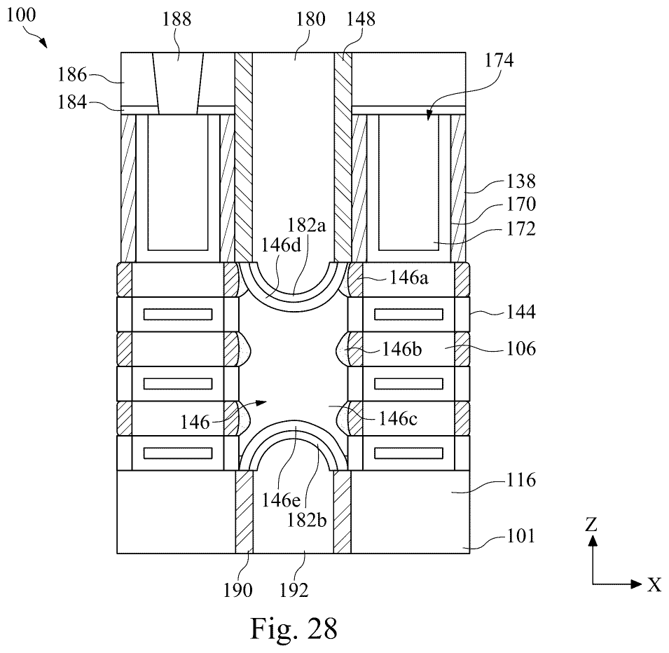

In FIG. 27, a silicide layer 182b is formed over the fourth epitaxial layer 146e. The silicide layer 182b may be metal silicide layer formed by any suitable process. As shown in FIG. 27, the silicide layer 182b has a curved profile. In some embodiments, an electrical conductivity of the silicide layer 182b is between an electrical conductivity of the respective S/D feature 146 (e.g., the fourth epitaxial layer 146e) and an electrical conductivity of a respective S/D contact 192 (FIG. 28). In some embodiments, a metal layer (not shown) is first formed on the semiconductor device structure 100. The metal layer may include Ti, Ni, Ru, Co, W, or other suitable metal. The metal layer may be deposited by any suitable process, such as ALD, CVD, or PVD. After the metal layer deposition, an annealing process is performed to react the S/D feature 146 (e.g., the fourth epitaxial layer 146e) with the metal layer, thereby forming the silicide layer 182b. The silicide layer 182b may include any suitable material, such as NiSi, TiSi, CoSi, RuSi, or WSi.

In FIG. 28, a backside S/D contact 192 is formed in the opening 152, over the silicide layer 182b, and between the sidewall portions of the dielectric layer 190. The backside S/D contact 192 is electrically connected to the corresponding S/D feature 146 via the silicide layer 182b. The backside S/D contact 192 may be electrically conductive and may include a material having one or more of Ru, Mo, Co, Ir, W, Ti, Ta, Cu, TiN or TaN. The backside S/D contact 192 may be formed by any suitable method, such as electro-chemical plating (ECP) or PVD. A planarization process, such as a CMP process, may be performed so the top surfaces of the backside S/D contact 180 and the substrate 101 are substantially co-planar, as shown in FIG. 28.

FIGS. 29A-29F are cross-sectional side views showing various formations of dopant clusters in the semiconductor device structure of FIG. 28, in accordance with some embodiments. In general, the dopant clusters may form according to a process where a dopant, such as boron, is extracted from one or more epitaxial layers 146b-146e defining the source/drain feature 146 and is subsequently precipitated into clusters. As used herein, the term “cluster,” for example “dopant cluster” or “boron cluster,” may refer to a particular material domain or aggregate within a bulk material that has a higher concentration of dopant, such as boron, compared to the concentration of dopant in the bulk material. For example, dopants doped in bulk epitaxial layers can individually occupy a lattice site of the crystalline structure, while dopant clusters can be an atom/molecule aggregation at the interface between two adjoining epitaxial layers and/or scattered in the respective epitaxial layers and not incorporated in the lattice structure. In general, the driving force behind the extraction and precipitation of the dopant clusters is thought to be a result of the epitaxial growth process and/or a result of the annealing processes associated with the formation of the silicide layers 182a, 182b by reacting a metal layer with the S/D feature 146, as described above. As described in connection with FIGS. 29A-29F, the dopant clusters may be formed at various different interfaces between material layers, and one or more of the following examples may be combined without limitation.

In FIG. 29A, one or more boron clusters 194a are formed at a first interface that is defined between the semiconductor material 146a and the first epitaxial layer 146b. In some embodiments, boron concentration in the boron clusters 194a is much higher than the boron concentration per unit volume in the respective non-clusters, such as the semiconductor material 146a and/or the first epitaxial layer 146b. In some embodiments, a concentration of boron in the boron clusters 194a can be greater than a maximum doping concentration of boron in the surrounding epitaxial layers, which may be based on the solid solubility limit of boron in the respective epitaxial layers. For example, the boron concentration in the boron clusters 194a can be between 2 times and 10 times greater than the boron concentration in the respective non-clusters. In some embodiments, the boron clusters 194a may be confined only to the semiconductor material 146a, the first epitaxial layer 146b, and the first interface defined therebetween, without extending into any other material layer. In some other embodiments, the boron clusters 194a may extend further into another material layer, such as the second epitaxial layer 146c. In such embodiments, in addition to the first interface, the boron clusters 194a also may be disposed at the interface between the first and second epitaxial layers 146b, 146c.

In FIG. 29B, one or more boron clusters 194b are formed at a second interface that is defined between the first epitaxial layer 146b and the second epitaxial layer 146c. In some embodiments, the boron clusters 194b may be confined only to the first epitaxial layer 146b, the second epitaxial layer 146c, and the second interface defined therebetween, without extending into any other material layer. In some other embodiments, the boron clusters 194b may extend further into another material layer, such as the semiconductor material 146a or the third or fourth epitaxial layers 146d, 146e. In such embodiments, in addition to the second interface, the boron clusters 194b also may be disposed at one or more respective interfaces between the other material layers. In some embodiments, multiple boron clusters 194b may be in contact with one another, which may result from the formation of multiple precipitation nodes that are positioned close together along a respective interface.

In FIG. 29C, one or more boron clusters 194c are formed at a third interface that is defined between the second epitaxial layer 146c and the third epitaxial layer 146d. In some embodiments, the boron clusters 194c may be confined only to the second epitaxial layer 146c, the third epitaxial layer 146d, and the third interface defined therebetween, without extending into any other material layer. In some other embodiments, the boron clusters 194c may extend further into another material layer, such as the first epitaxial layer 146b or the silicide layer 182a. In such embodiments, in addition to the third interface, the boron clusters 194c also may be disposed at one or more respective interfaces between the other material layers.

Likewise, one or more boron clusters 194d are formed at a fourth interface that is defined between the second epitaxial layer 146c and the fourth epitaxial layer 146e. In some embodiments, the boron clusters 194d may be confined only to the second epitaxial layer 146c, the fourth epitaxial layer 146e, and the fourth interface defined therebetween, without extending into any other material layer. In some other embodiments, the boron clusters 194d may extend further into another material layer, such as the first epitaxial layer 146b or the silicide layer 182b. In such embodiments, in addition to the fourth interface, the boron clusters 194d also may be disposed at one or more respective interfaces between the other material layers.

In FIG. 29D, one or more boron clusters 194e are formed at a fifth interface that is defined between the first epitaxial layer 146b and the third epitaxial layer 146d. In some embodiments, the boron clusters 194e may be confined only to the first epitaxial layer 146b, the third epitaxial layer 146d, and the fifth interface defined therebetween, without extending into any other material layer. In some other embodiments, the boron clusters 194e may extend further into another material layer, such as the second epitaxial layer 146c, the semiconductor material 146a, or the silicide layer 182a. In such embodiments, in addition to the fifth interface, the boron clusters 194e also may be disposed at one or more respective interfaces between the other material layers.

As shown in FIG. 29E, one or more boron clusters 194f are primarily formed at certain crystal lattice positions, such as at the (111) surface or the (111) cross-section. In some embodiments, a total number of boron clusters in the source/drain feature 146 (e.g., in a single source/drain feature) may range between 0 and 20.

In FIG. 29F, there are various different types of boron clusters that may be included in any of the embodiments described herein. For example, a first type of boron cluster 196a may have a circular shape in cross-section. In some embodiments, a radius R of the circular shape may be between 1 nm and 10 nm. A second type of boron cluster 196b may have an ellipse shape in cross-section. In some embodiments, respective dimensions of the ellipse shape in the X-direction and Z-direction may be between 1 nm and 10 nm. A third type of boron cluster 196c may have an irregular shape in cross-section. In some embodiments, dimensions of the irregular shape, such as R1, R2, and angle A1 between R1 and R2 may be between 1 nm and 10 nm, 1 nm and 10 nm, and 20° and 60°, respectively.

Embodiments of the present disclosure provide a semiconductor device structure including a source/drain feature having a plurality of epitaxial layers having a structure and composition that is particularly advantageous to lower the contact resistance of the source/drain feature, at least in the vicinity of the respective S/D contact. In particular, the source/drain feature includes a first epitaxial layer adjacent to a first plurality of semiconductor layers (e.g., nanosheets), a second epitaxial layer over the first epitaxial layer, and a third epitaxial layer on the first and second epitaxial layers. Notably, to form this structure, the method may include forming the first and second epitaxial layers and forming a CESL and ILD over the first and second epitaxial layers. Then, one or more etching processes are performed to remove portions of the ILD layer, CESL, and second epitaxial layer to form an opening, after which the third epitaxial layer is formed over the second epitaxial layer in the opening. In some embodiments, a fourth epitaxial layer is formed on the second epitaxial layer, where the first and second epitaxial layers are disposed between the third and fourth epitaxial layers. For example, the third epitaxial layer can be formed on a frontside of the substrate, whereas the fourth epitaxial layer is formed on a backside of the substrate. The third and fourth epitaxial layers include a semiconductor material doped with a dopant. In some embodiments, to improve device performance, a composition of the semiconductor material in the third epitaxial layer is different from a composition of the semiconductor material in the fourth epitaxial layer and/or a concentration of the dopant in the third epitaxial layer is different from a concentration of the dopant in the fourth epitaxial layer. To lower the contact resistance, a temperature associated with the formation of the third epitaxial layer may be lower than respective temperatures associated with the formation of the first and second epitaxial layers. Furthermore, to prevent damage to frontside metal, a temperature associated with the formation of the fourth epitaxial layer may be lower than the temperature associated with the formation of the third epitaxial layer.

An embodiment is a semiconductor device structure. The semiconductor device structure includes an isolation structure extending over a substrate; an interlayer dielectric (ILD) layer disposed over the isolation structure, wherein each of the isolation structure and the ILD layer has a dielectric constant that is about 3 to about 5; a contact etch stop layer (CESL) disposed between the ILD layer and the isolation structure; a channel region comprising a first plurality of semiconductor layers; and a source/drain feature having a first epitaxial layer adjacent to the first plurality of semiconductor layers, a second epitaxial layer over the first epitaxial layer, and a third epitaxial layer interfacing the first and second epitaxial layers, wherein the first epitaxial layer and the second epitaxial layer are doped with a dopant, wherein a concentration of the dopant in the first epitaxial layer is different from a concentration of the dopant in the second epitaxial layer, and wherein a thickness of the source/drain feature is different from a width of the source/drain feature in a cross-sectional view.

Another embodiment is a method. The method includes forming an isolation structure extending over a substrate; forming a source/drain feature having a first epitaxial layer, a second epitaxial layer on the first epitaxial layer, a third epitaxial layer on the second epitaxial layer, and a fourth epitaxial layer on the second epitaxial layer, wherein the first and second epitaxial layers are disposed between the third and fourth epitaxial layers, wherein the third and fourth epitaxial layers comprise a semiconductor material doped with a dopant, wherein one or more dopant clusters are formed at respective interfaces between the first and third epitaxial layers and the second and fourth epitaxial layers, and wherein at least one of: a composition of the semiconductor material in the third epitaxial layer is different from a composition of the semiconductor material in the fourth epitaxial layer; or a concentration of the dopant in the third epitaxial layer is different from a concentration of the dopant in the fourth epitaxial layer; depositing a contact etch stop layer (CESL) over the source/drain feature and the isolation structure; depositing a first interlayer dielectric (ILD) layer over the CESL, wherein each of the isolation structure and the first ILD layer has a dielectric constant that is about 3 to about 5; depositing an etch stop layer (ESL) over a top surface of the CESL and a top surface of the first ILD layer; and depositing a second ILD layer over the ESL, wherein a thickness of the first ILD layer is greater than a thickness of the second ILD layer.

A further embodiment is a method. The method includes forming a first plurality of semiconductor layers over a substrate; removing a portion of the first plurality of semiconductor layers; depositing a first epitaxial layer adjacent to the first plurality of semiconductor layers; depositing a second epitaxial layer over the first epitaxial layer; depositing a contact etch stop layer (CESL) over the second epitaxial layer; depositing an interlayer dielectric layer (ILD) over the CESL, wherein a dielectric constant of the CESL is greater than a dielectric constant of the ILD layer, and wherein the ILD layer has a dielectric constant that is about 3 to about 5; performing one or more etching processes to remove portions of the ILD layer, CESL, and second epitaxial layer to form an opening; forming a third epitaxial layer over the second epitaxial layer in the opening, wherein a temperature associated with the formation of the third epitaxial layer is lower than respective temperatures associated with the formation of the first and second epitaxial layers; and forming a source/drain contact in the opening.

A further embodiment is a method that includes forming a substrate having a frontside and a backside; forming an active region over the frontside of the substrate, the active region comprising a channel region and a source/drain region adjacent to the channel region; forming a gate structure over the channel region and interfacing at least three surfaces of the channel region; forming a gate spacer disposed along a sidewall of the gate structure; forming a source/drain feature over the source/drain region and adjacent to a sidewall of the channel region, wherein forming the source/drain feature includes: forming a first epitaxial layer adjacent to the channel region; and forming a second epitaxial layer over the first epitaxial layer; forming a contact etch stop layer (CESL) over the source/drain feature; forming an interlayer dielectric (ILD) layer over the CESL; performing one or more first etching processes toward the frontside to remove respective portions of the ILD layer and CESL, and to remove a frontside portion of the second epitaxial layer; forming a frontside third epitaxial layer over the frontside portion of the second epitaxial layer; forming a frontside source/drain contact extending through the ILD layer and the CESL, wherein the frontside source/drain contact is spaced apart from the gate structure by the CESL, the ILD layer, and the gate spacer; performing one or more second etching processes toward the backside to expose a backside portion of the second epitaxial layer; forming a backside third epitaxial layer over the backside portion of the second epitaxial layer, wherein a temperature associated with the formation of the backside third epitaxial layer is lower than a temperature associated with the formation of the frontside third epitaxial layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
an isolation structure extending over a substrate;
an interlayer dielectric (ILD) layer disposed over the isolation structure, wherein each of the isolation structure and the ILD layer has a dielectric constant that is about 3 to about 5;
a contact etch stop layer (CESL) disposed between the ILD layer and the isolation structure;
a channel region comprising a first plurality of semiconductor layers; and
a source/drain feature having a first epitaxial layer adjacent to the first plurality of semiconductor layers, a second epitaxial layer over the first epitaxial layer, and a third epitaxial layer interfacing the first and second epitaxial layers, wherein the first epitaxial layer and the second epitaxial layer are doped with a dopant, wherein a concentration of the dopant in the first epitaxial layer is different from a concentration of the dopant in the second epitaxial layer, and wherein a thickness of the source/drain feature is different from a width of the source/drain feature in a cross-sectional view.

2. The semiconductor device structure of claim 1, wherein the third epitaxial layer is disposed on the first and second epitaxial layers towards a frontside of the substrate, the source/drain feature further comprising a fourth epitaxial layer disposed on the second epitaxial layer towards a backside of the substrate.

3. The semiconductor device structure of claim 2, wherein the first and second epitaxial layers are disposed between the third and fourth epitaxial layers.

4. The semiconductor device structure of claim 1, wherein the third epitaxial layer is doped with the dopant, and wherein the concentration of the dopant in the third epitaxial layer is greater than respective concentrations of the dopant in the first and second epitaxial layers.

5. The semiconductor device structure of claim 1, wherein the first, second, and third epitaxial layers are formed from SiGe and wherein a concentration of Ge in the third epitaxial layer is greater than respective concentrations of Ge in the first and second epitaxial layers.

6. The semiconductor device structure of claim 1, wherein one or more dopant clusters are formed at an interface between the first and third epitaxial layers.

7. The semiconductor device structure of claim 6, wherein one or more additional dopant clusters are formed at a different interface between the second and third epitaxial layers.

8. A method, comprising:
forming an isolation structure extending over a substrate;
forming a source/drain feature having a first epitaxial layer, a second epitaxial layer on the first epitaxial layer, a third epitaxial layer on the second epitaxial layer, and a fourth epitaxial layer on the second epitaxial layer, wherein the first and second epitaxial layers are disposed between the third and fourth epitaxial layers, wherein the third and fourth epitaxial layers comprise a semiconductor material doped with a dopant, wherein one or more dopant clusters are formed at respective interfaces between the first and third epitaxial layers and the second and fourth epitaxial layers, and wherein at least one of:
a composition of the semiconductor material in the third epitaxial layer is different from a composition of the semiconductor material in the fourth epitaxial layer; or
a concentration of the dopant in the third epitaxial layer is different from a concentration of the dopant in the fourth epitaxial layer;
depositing a contact etch stop layer (CESL) over the source/drain feature and the isolation structure;
depositing a first interlayer dielectric (ILD) layer over the CESL, wherein each of the isolation structure and the first ILD layer has a dielectric constant that is about 3 to about 5;
depositing an etch stop layer (ESL) over a top surface of the CESL and a top surface of the first ILD layer; and
depositing a second ILD layer over the ESL, wherein a thickness of the first ILD layer is greater than a thickness of the second ILD layer.

9. The method of claim 8, wherein the composition of the semiconductor material in the third epitaxial layer is different from the composition of the semiconductor material in the fourth epitaxial layer.

10. The method of claim 9, wherein the third and fourth epitaxial layers are formed from SiGe, and wherein a concentration of Ge in the fourth epitaxial layer is greater than a concentration of Ge in the third epitaxial layer.

11. The method of claim 8, wherein the concentration of the dopant in the third epitaxial layer is different from the concentration of the dopant in the fourth epitaxial layer.

12. The method of claim 11, wherein the dopant is boron, and wherein the concentration of B dopant in the fourth epitaxial layer is greater than the concentration of B dopant in the third epitaxial layer.

13. The method of claim 8, wherein at least one of the first or second epitaxial layers is formed at a first temperature between 400 °C and 850 °C, and wherein at least one of the third or fourth epitaxial layers is formed at a second temperature between 350 °C and 600 °C.

14. The method of claim 8, wherein contact resistance is lower in the third and fourth epitaxial layers compared to the second epitaxial layer.

15. A method, comprising:
forming a first plurality of semiconductor layers over a substrate;
removing a portion of the first plurality of semiconductor layers;
depositing a first epitaxial layer adjacent to the first plurality of semiconductor layers;
depositing a second epitaxial layer over the first epitaxial layer;
depositing a contact etch stop layer (CESL) over the second epitaxial layer;
depositing an interlayer dielectric layer (ILD) over the CESL, wherein a dielectric constant of the CESL is greater than a dielectric constant of the ILD layer, and wherein the ILD layer has a dielectric constant that is about 3 to about 5;
performing one or more etching processes to remove portions of the ILD layer, CESL, and second epitaxial layer to form an opening;
forming a third epitaxial layer over the second epitaxial layer in the opening, wherein a temperature associated with the formation of the third epitaxial layer is lower than respective temperatures associated with the formation of the first and second epitaxial layers; and
forming a source/drain contact in the opening.

16. The method of claim 15, wherein at least one of the first or second epitaxial layers is formed at a first temperature between 400 °C and 850 °C, and wherein the third epitaxial layer is formed at a second temperature between 350 °C and 600 °C.

17. The method of claim 15, further comprising:
forming a backside opening on a backside of the substrate; and
forming a fourth epitaxial layer over the second epitaxial layer in the backside opening.

18. The method of claim 17, wherein a temperature associated with the formation of the fourth epitaxial layer is less than a temperature associated with the formation of the third epitaxial layer.

19. The method of claim 15, forming a third epitaxial layer over the second epitaxial layer in the opening defines an interface between the third epitaxial layer and the first epitaxial layer.

20. The method of claim 19, further comprising forming a silicide layer over the third epitaxial layer via an annealing process, wherein the annealing process causes precipitation of one or more dopant clusters at the interface.
